(19) United States
(12) Patent Application Publication
(10) Pub. No.: US 2008/0176387 A1
(43) Pub. Date: Jul. 24, 2008

(54) PLASMA DOPING METHODS USING MULTIPLE SOURCE GASES

(75) Inventors: Jong-hoon Kang, Gyeonggi-do (KR); Tai-su Park, Gyeonggi-do (KR); Si-young Choi, Gyeonggi-do (KR); Min-jin Kim, Seoul (KR)

Correspondence Address: MYERS BIGEL SIBLEY & SAJOVEC, PO BOX 37428, RALEIGH, NC, 27627, US

(73) Assignee: Samsung Electronics Co., Ltd.

(21) Appl. No.: 11/753,791

(22) Filed: May 25, 2007

(30) Foreign Application Priority Data
Jan. 23, 2007 (KR) 10-2007-0007250

(51) Int. Cl. H01L 21/265

(52) U.S. Cl. 438/513; 257/E21.334

(57) ABSTRACT

A plasma doping method includes providing a substrate including a layer to be doped inside a chamber, and supplying first and second source gases to the layer to achieve a desired doping concentration. The first source gas includes a component configured to increase a thickness of the layer, and the second gas includes a component configured to reduce a thickness of the layer.

### CROSS-REFERENCE TO RELATED APPLICATIONS

This application claims priority from Korean Patent Application No. 10-2007-0007250, filed on Jan. 23, 2007, in the Korean Intellectual Property Office, the disclosure of which is incorporated by reference herein in its entirety.

### FIELD OF THE INVENTION

The present invention relates to semiconductor devices, and more particularly, to methods of manufacturing semiconductor devices.

### BACKGROUND OF THE INVENTION

Plasma doping methods may use relatively low ion acceleration voltages, and may be used to inject ions at a higher density than other ion injection methods. Such plasma doping methods can be used to uniformly inject ions into a relatively wide area.

FIG. 1 is a cross-sectional view of a conventional plasma doping apparatus for use with conventional plasma doping methods. Here, BF₃ is used as a source gas.

Referring to FIG. 1, the plasma doping apparatus has a structure in which a source electrode 50 and a cathode electrode 20 are provided inside a chamber 10 and a substrate 40 is positioned between the source and cathode electrodes 50 and 20. The source gas is excited into plasma 60, and ions inside the excited plasma 60 are injected into the substrate 40 placed on a platen 30. If a bias voltage is applied to the cathode electrode 20, the ions inside the plasma 60 may be accelerated toward the substrate 40. Thus, a surface of the substrate 40 may be doped with the ions from the plasma 60.

However, in conventional plasma doping methods, desired ions may not be selectively injected, and thus the substrate 40 may be doped with undesired ions and/or radicals. For example, when BF₃ is used for boron (B) doping as shown in FIG. 1, ions and radicals such as B³⁺, BF₂₊, BF⁺, F⁺, etc. are formed. As such, an undesired process such as etching may occur in a doped layer on the substrate 40 due to fluorine (F) ions. In addition, if B₂H₆ is used, a new layer may be deposited on the doped layer during a doping process, and thus a smaller number of ions than desired may be injected.

Accordingly, in conventional methods, etching of the doped layer due to ions and/or radicals in plasma and/or the formation of new layers on the doped layer may be difficult to avoid. Thus, a thickness of the doped layer may vary from a desired thickness and/or a desired doping density may not be obtained at a desired depth (or a desired position).

### SUMMARY OF THE INVENTION

Some embodiments of the present invention provide plasma doping methods for maintaining a substantially uniform thickness of a doped layer after doping and obtaining a desired doping density according to a depth of the doped layer.

According to some embodiments of the present invention, a method of plasma doping may include providing a substrate including a layer to be doped inside a chamber; and supplying first and second source gases to the layer to achieve a desired doping concentration. The first source gas may include a component configured to increase a thickness of the layer, and the second source gas may include a component configured to reduce a thickness of the layer.

In some embodiments, the thickness of the layer prior to plasma doping may be substantially similar to that after the plasma doping is completed.

In other embodiments, the first source gas may be a deposition gas configured to increase the thickness of the layer by a deposition process, and the second source gas may be an etching gas configured to reduce the thickness of the layer by an etching process.

In some embodiments, the layer may be formed of polysilicon or a metal thin film. When the doped layer is formed of polysilicon, the first gas may be SiH₄ and the second gas may be a gas comprising fluorine, such as BF₃.

In other embodiments, the method may further include supplying a third gas including a component configured to increase a thickness of the layer to achieve the desired doping concentration. When the doped layer is formed of polysilicon, the third gas may be a gas including hydrogen, such as B₂H₆.

According to other embodiments of the present invention, a plasma doping method may include providing a substrate including a layer to be doped inside a chamber; and supplying first and second source gases to the layer to perform plasma doping. The first source gas may includes a component configured to increase a thickness of the layer, and the second source gas may include a component configured to reduce a thickness of the layer. A flux of the first and/or second source gases may be varied for a time during which plasma doping is performed.

According to further embodiments of the present invention, a plasma doping method may include providing a substrate including a layer to be doped inside a chamber, and alternately supplying first and second source gases to the layer to perform plasma doping. The first source gas may include a component configured to increase a thickness of the layer, and the second source gas may include a component configured to reduce a thickness of the layer.

Other devices and/or methods of fabrication according to some embodiments will become apparent to one with skill in the art upon review of the following drawings and detailed description. It is intended that all such additional methods and/or devices be included within this description, be within the scope of the invention, and be protected by the accompanying claims.

### BRIEF DESCRIPTION OF THE DRAWINGS

FIG. 1 is a cross-sectional view of a conventional plasma doping apparatus illustrating a conventional plasma doping method;

FIG. 2 is a cross-sectional view of a p-channel metal oxide semiconductor (PMOS) transistor according to some embodiments of the present invention;

FIG. 3 is a graph illustrating a secondary ion mass spectrometry (SIMS) profile of boron (B) in a gate dielectric layer and a conductive layer of FIG. 2 after high density B is doped according to some embodiments of the present invention;

FIGS. 4A and 4B illustrate doping steps in which deposition gases are provided at a flux greater than etching gases according to some embodiments of the present invention;

FIGS. 5A and 5B illustrate doping steps in which etching gases are provided at a flux greater than deposition gases according to other embodiments of the present invention;

FIGS. 6A through 6D illustrate doping steps in which deposition gases are provided at a flux greater than etching gases according to further embodiments of the present invention;

FIGS. 7A and 7B illustrate doping steps in which etching gases are provided at a flux greater than deposition gases according to still further embodiments of the present invention;

FIG. 8A is a graph illustrating a doping step in which a deposition gas is provided at a flux greater than an etching gas according to some embodiments of the present invention;

FIG. 8B is a graph illustrating a doping step in which an etching gas is provided at a flux greater than a deposition gas, according to some embodiments of the present invention;

FIG. 9A is a graph illustrating plasma doping methods according to some embodiments of the present invention;

FIG. 9B is a cross-sectional view illustrating a doping density of a doped layer in a doping step between tₛ and tᵢ, according to some embodiments of the present invention;

FIG. 9C is a cross-sectional view illustrating a doping density of a doped layer in a doping step between tᵢ and t_{f}, according to some embodiments of the present invention;

FIG. 10A is a graph illustrating plasma doping methods according to other embodiments of the present invention;

FIG. 10B is a cross-sectional view illustrating a doping density of a doped layer in a doping step between tₛ and tᵢ, according to other embodiments of the present invention;

FIG. 10C is a cross-sectional view illustrating a doping density of a doped layer in a doping step between tᵢ and t_{f}, according to other embodiments of the present invention;

FIG. 11 is a graph illustrating variations in doping density and thickness of a doped layer in plasma doping methods according to some embodiments of the present invention; and

FIGS. 12A and 12B are cross-sectional views illustrating plasma doping methods according to some embodiments of the present invention.

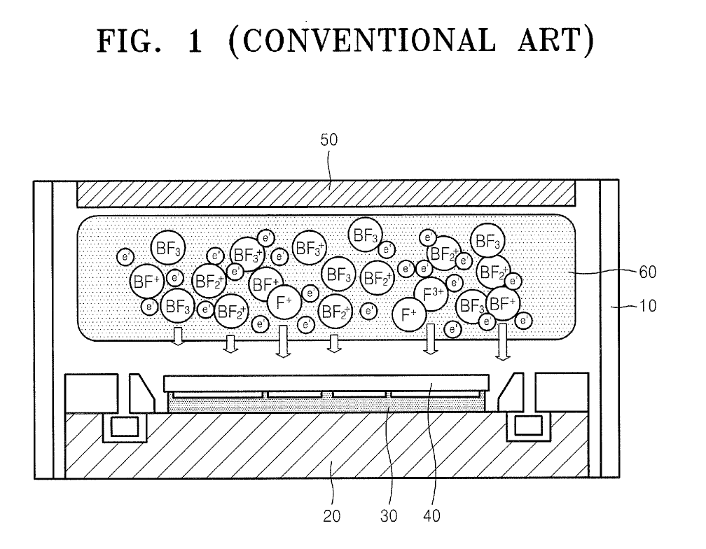

### DETAILED DESCRIPTION OF EMBODIMENTS OF THE INVENTION

The present invention is described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. In the drawings, the size and relative sizes of layers and regions may be exaggerated for clarity. Like numbers refer to like elements throughout.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath”, “below”, “lower”, “under”, “above”, “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” or “under” other elements or features would then be oriented “above” the other elements or features. Thus, the exemplary terms “below” and “under” can encompass both an orientation of above and below. The device may be otherwise oriented (rotated 90 degrees or at other orientations) and the spatially relative descriptors used herein interpreted accordingly. In addition, it will also be understood that when a layer is referred to as being “between” two layers, it can be the only layer between the two layers, or one or more intervening layers may also be present.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items.

It will be understood that when an element or layer is referred to as being “on”, “connected to”, “coupled to”, or “adjacent to” another element or layer, it can be directly on, connected, coupled, or adjacent to the other element or layer, or intervening elements or layers may be present. In contrast, when an element is referred to as being “directly on,” “directly connected to”, “directly coupled to”, or “immediately adjacent to” another element or layer, there are no intervening elements or layers present.

Embodiments of the invention are described herein with reference to cross-section illustrations that are schematic illustrations of idealized embodiments (and intermediate structures) of the invention. As such, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and/or the present specification and will not be interpreted in an idealized or overly formal sense unless expressly so defined herein.

Some embodiments of the present invention may provide a plasma doping method using a first source gas for depositing a new layer on a doped layer, a second source gas for etching the doped layer to achieve desired doping, and/or a third source gas for depositing a new layer on the doped layer to adjust and/or achieve a desired doping. For this purpose, transistors according to some embodiments of the present invention will be exemplarily described to illustrate characteristics of the first, second, and third source gases; however, in some embodiments, fewer or more source gases may be used. Also, methods of applying the first, second, and third source gases will be described in detail.

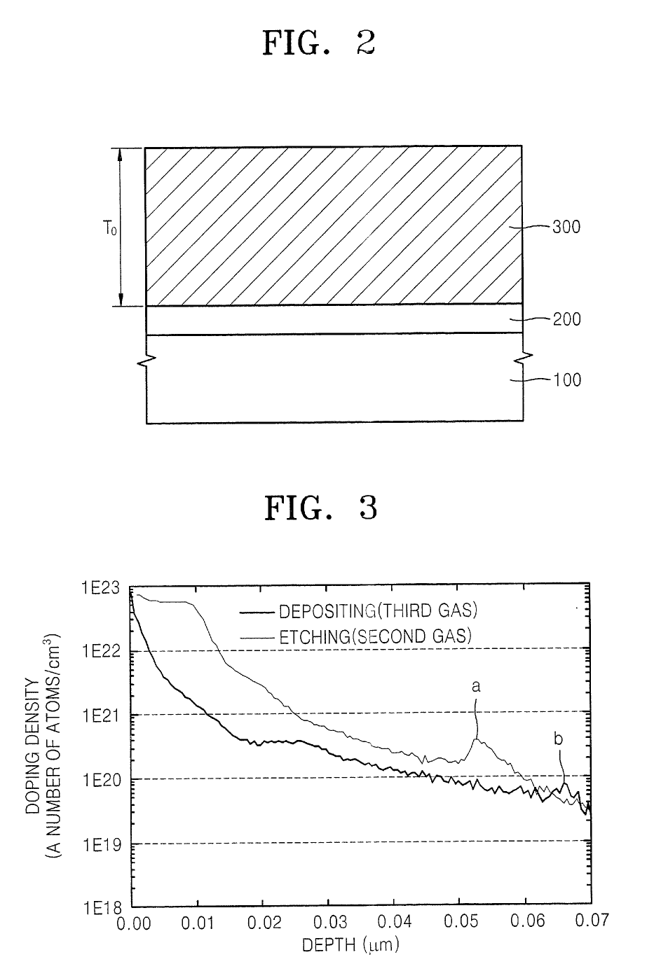

FIG. 2 is a cross-sectional view of a positive channel metal oxide semiconductor (PMOS) transistor according to some embodiments of the present invention. Referring to FIG. 2, a gate dielectric layer 200 is formed on a semiconductor substrate 100, e.g., a p-type silicon substrate. The gate dielectric layer 200 may be a silicon oxide layer which is thermally oxidized using a thermal oxidation method, a silicon nitride layer which is deposited using a chemical vapor deposition (CVD) method, and/or another high dielectric layer that has a high dielectric constant k. A conductive layer 300 is formed on the gate dielectric layer 200. The conductive layer 300 may be, for example, a polysilicon layer or a metal thin film.

In FIG. 2, a polysilicon layer is used as the conductive layer 300. However, a metal thin film may be used as the conductive layer 300 in other embodiments of the present invention. The polysilicon layer is doped with n-type dopant and then counter doped with p+-type dopant or high density boron (B) using a plasma doping method according to some embodiments to be used as a PMOS.

FIG. 3 is a graph illustrating a secondary ion mass spectrometry (SIMS) profile of B in the gate dielectric layer 200 and the conductive layer 300 of FIG. 2 after the high density B is counter doped. The counter doping was performed using the second and third gases, and then thermal treatment was performed at a temperature of about 950° C. for about 30 seconds. The second gas is BF₃, and the third gas is B₂H₆. Also, as used herein, a doping depth refers to a distance determined from an exposed surface of the polysilicon layer to the gate dielectric layer 200.

Referring to FIG. 3, if a thermal treatment is performed, the doped B is diffused into the polysilicon layer. Thus, B may be accumulated on an interface between the polysilicon layer 300 and the gate dielectric layer 200. Here, since a boron peak a is generated on the interface, a position of the interface between the polysilicon layer 300 and the gate electric layer 200 can be detected from a position of the boron peak a.

More particularly, if the second gas BF₃ is used, the boron peak a (at a depth of about 0.05 μm) is formed by doping and thermal treatment according to some embodiments. The boron peak a indicates that the doped polysilicon layer is etched during plasma doping methods according to some embodiments using the second gas. If the third gas B₂H₆ is used, a boron peak b (at a depth of about 0.065 μm) is formed by doping and thermal treatment according to some embodiments. The boron peak b indicates that a new/additional layer is deposited on a polysilicon layer during plasma doping according to some embodiments using the third gas.

If plasma doping is performed using the second source gas, a profile of B having a relatively high density can be obtained. If plasma doping is performed using the third source gas, a profile of B having a relatively low density can be obtained. This phenomenon may depend on the type of source gas used to form the plasma. For example, if a fluoride gas is used as a second source gas, the polysilicon layer 300 may be doped with ions and radicals related to F existing in the plasma which may result in etching of the polysilicon layer, also known as plasma etching. If a hydride gas is used as a third source gas, a new deposited layer is formed by ions and/or radicals related to hydrogen (H), which may reduce and/or prevent B from being injected into the polysilicon layer 300.

The second source gas (for etching a doped layer to achieve a desired doping) and the third source gas (for depositing a new layer on the doped layer to achieve a desired doping) have been described with respect to a PMOS device. Also, a first source gas for depositing a new layer on a doped layer prior to performing doping may be applied in some embodiments. For example, if SiH₄ is used as a first gas for forming plasma in a PMOS, a new layer may be formed on a polysilicon layer due to plasma doping using the first gas while a doping process is performed using a second gas. The new layer formed by the first source gas may reduce and/or prevent B from being injected as described above with reference to the third source gas.

The first, second, and/or third source gases may be selected based on the layer to be doped. For example, the layer may be a metal thin film, and the doping material may be phosphorus (P). Thus, a combination of a first gas for depositing a new layer on a doped layer, a second gas for etching a doped layer to achieve desired doping, and/or a third gas for depositing a new layer on a doped layer to achieve desired doping may be selected and applied according to the characteristics of the layer to be doped.

A plasma doping method using first, second, and third source gases according to some embodiments of the present invention will now be described. Here, a doped layer is a polysilicon layer as described with reference to FIG. 2. Also, the first, second, and third gases are SiH₄, BF₃, and B₂H₆, respectively, as described with reference to FIG. 3. The first and third gases may be referred to herein as deposition gases, and the second gas may be referred to as an etching gas.

The plasma doping method will be described with reference to four cases: supplying the first, second, and third source gases at substantially constant fluxes; varying the fluxes of the first, second, and third source gases; stopping supplying ones of the first, second, and third source gases; and alternately supplying the first, second, and third source gases. However, such plasma doping methods are provided as examples, and thus, may be modified in various forms according to the scope of the present invention.

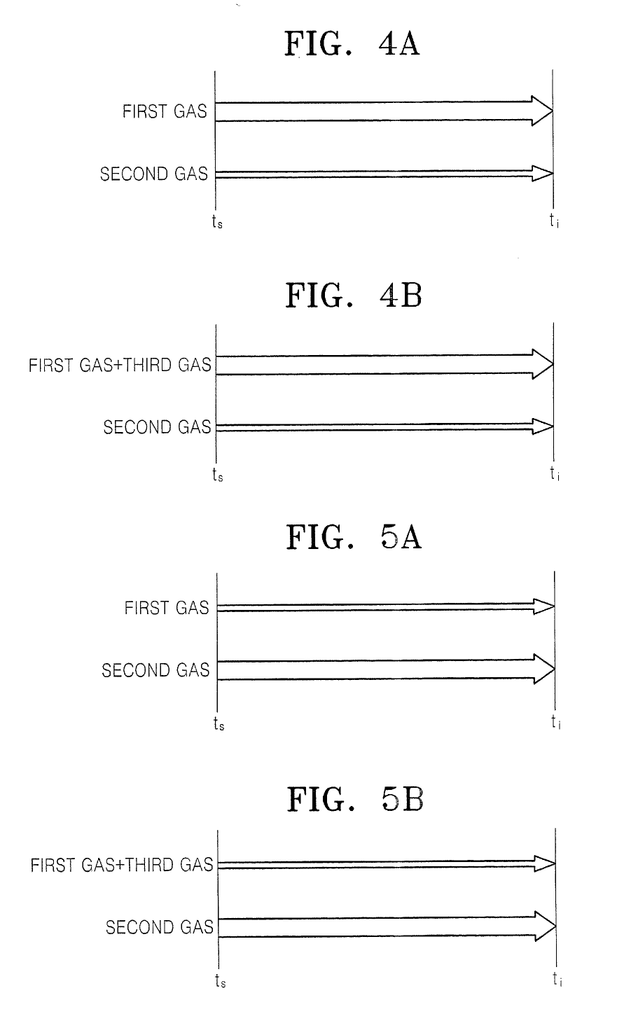

FIGS. 4A through 5B illustrate plasma doping methods according to some embodiments of the present invention. Arrows denote temporal flows of gases, and thicknesses of the arrows denote fluxes of the gases. Also, tₛ denotes a starting time of doping, and tᵢ denotes an ending time of a corresponding doping step. Here, the corresponding doping process may correspond to an entire process of plasma doping or may be a part of the entire process.

FIGS. 4A and 4B illustrate doping steps in which deposition gases have a greater flux than etching gases, and FIGS. 5A and 5B illustrate doping steps in which etching gases have a greater flux than deposition gases.

Referring to FIG. 4A, first and second source gases are simultaneously supplied at substantially constant fluxes into the chamber 10 of FIG. 2 in a doping step between tₛ and tᵢ. The first gas includes a component of a doped layer and deposits a new layer on the doped layer. The second gas etches the doped layer to achieve a desired doping. For example, the first gas may be SiH₄, and the second gas may be BF₃. As such, BF₃ may etch the polysilicon layer in a boron doping process, while SiH₄ may deposit a new polysilicon layer on the etched doped layer.

Referring to FIG. 4B, a mixture of first and third source gases and a second source gas are simultaneously supplied into the chamber 10 in a doping step between tₛ and tᵢ. The first gas includes a component of a doped layer and deposits a new layer on the doped layer. The second gas etches the doped layer, and the third gas deposits a new layer on the doped layer to achieve a desired doping. For example, the first, second, and third gases may be SiH₄, BF₃, and B₂H₆, respectively. Here, BF₃ may etch the polysilicon layer in a boron doping process, and SiH₄ and B₂H₆ may deposit a new polysilicon layer on the etched doped layer.

As described above with reference to FIGS. 4A and 4B, in a doping step in which the flux of a deposition gas is greater than that of etching gas, a thickness of a doped layer may be increased during doping. Thus, as described with reference to FIG. 3, a density profile of a doped layer may be reduced.

Referring to FIGS. 5A and 5B, processes of supplying source gases may be similar to those described with reference to FIGS. 4A and 4B. However, as the flux of the etching gas is greater than that of the deposition gases in the doping steps of FIGS. 5A and 5B, the thicknesses of doped layers may be decreased. Thus, as described with reference to FIG. 3, density profiles of the doped layers may be increased.

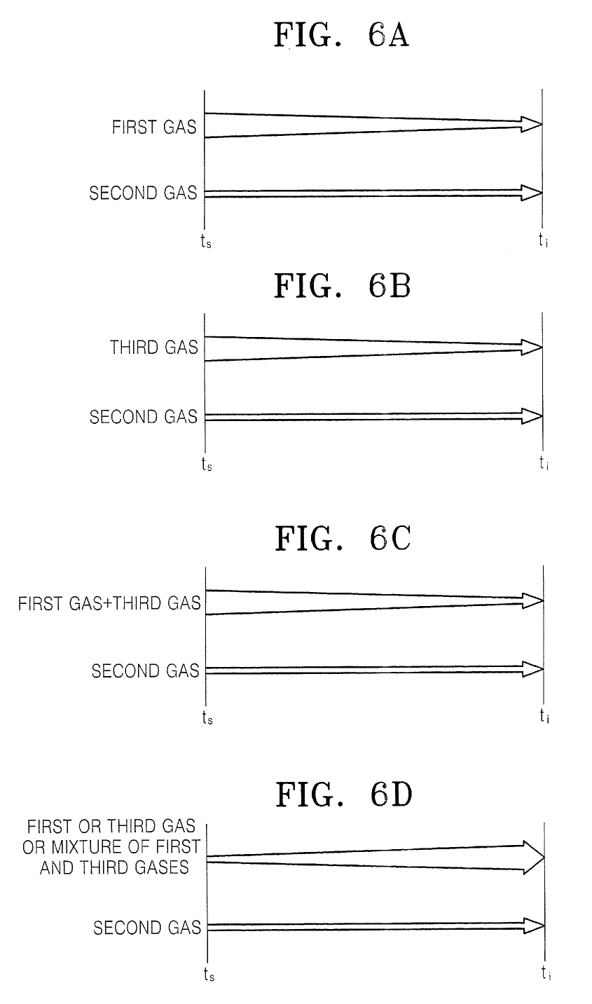

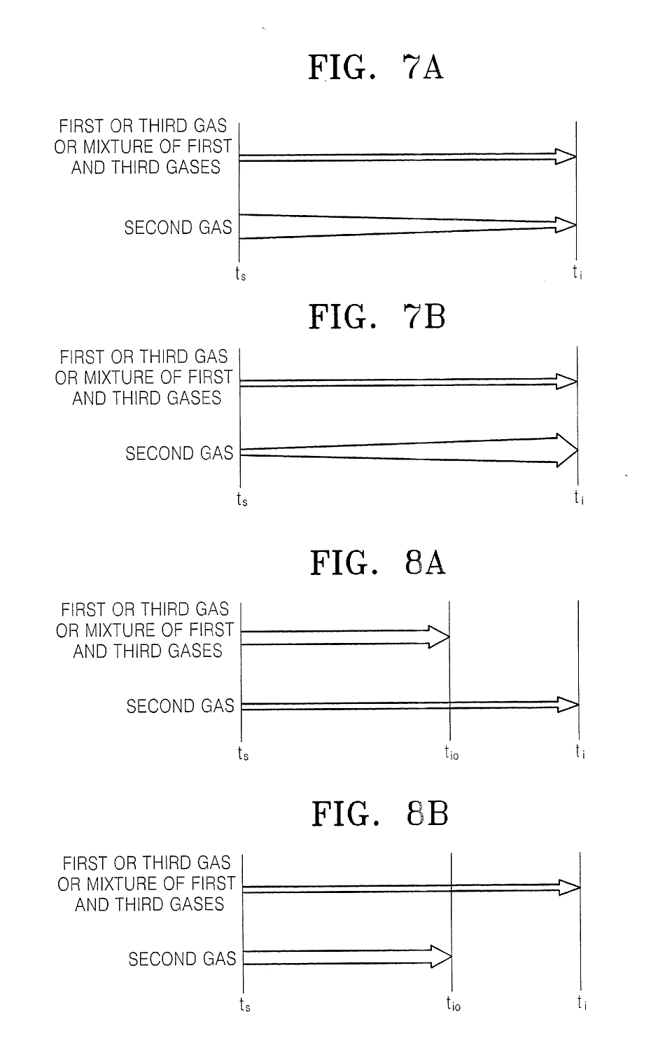

FIGS. 6A through 7B illustrate plasma doping methods according to further embodiments of the present invention. Meanings of arrows and doping steps are similar to those described with reference to FIGS. 4A through 5B. FIGS. 6A through 6D illustrate doping steps in which deposition gases have a greater flux than etching gases, and FIGS. 7A and 7B illustrate doping steps in which etching gases have a greater flux than deposition gases.

Referring to FIG. 6A, first and second source gases are simultaneously supplied into a chamber with a flux of the first gas gradually decreasing and a flux of a second gas at a substantially constant level in a doping step between tₛ and tᵢ. The first gas includes a component of a doped layer and deposits a new layer on the doped layer in the doping step. Also, the second gas etches the doped layer to achieve a desired doping in the doping step. For example, the first gas may be SiH₄, and the second gas may be BF₃. Here, BF₃ may etch the polysilicon layer in a boron doping process, and SiH₄ may deposit a new polysilicon layer on the etched doped layer.

Referring to FIG. 6B, third and second source gases are simultaneously supplied into a chamber with a flux of the third gas gradually decreasing and a flux of the second gas at a substantially constant level in a doping step between tₛ and tᵢ. The second gas etches a doped layer in the doping step. Also, the third gas deposits a new layer on the doped layer to achieve the desired doping. For example, the second gas may be BF₃, and the third gas may be B₂H₆. Here, BF₃ may etch the polysilicon layer in a boron doping process, and B₂H₆ may deposit a new polysilicon layer on the etched doped layer.

Referring to FIG. 6C, a mixture of first and third source gases and a second are simultaneously supplied into a chamber with a flux of the mixture gradually decreasing and a flux of the second gas at a substantially constant level in a doping step between tₛ and tᵢ. The first gas includes a component of a doped layer and deposits a new layer on the doped layer. Also, the second gas etches the doped layer in the doping step, and the third gas deposits a new layer on the doped layer to achieve the desired doping. For example, the first, second, and third gases may be sources SiH₄, BF₃, and B₂H₆, respectively. Here, BF₃ may etch the polysilicon layer in a boron doping process, and SiH₄ and B₂H₆ may deposit a new polysilicon layer on the etched doped layer.

Referring to FIG. 6D, a first source gas, a third source gas, and/or a mixture of the first and third source gases and a second source gas are simultaneously supplied into a chamber with a flux of the first or third gas or the mixture thereof gradually increasing and a flux of the second gas substantially constant. A doping step of FIG. 6D is similar to those described with reference to FIGS. 6A through 6C except for variations of the fluxes.

Since the flux of the deposition gases is greater than that of the etching gases in the doping steps described with reference to FIGS. 6A through 6D, thicknesses of doped layers may be increased. Thus, as described with reference to FIG. 3, a density profile of a doped layer may be reduced. However, the flux of one or more of the deposition gases can be changed to adjust a thickness of the new layer deposited on the doped layer.

Referring to FIGS. 7A and 7B, processes of supplying source gas may be similar to those described with reference to FIGS. 6A through 6D, except that fluxes of second gases may be varied. However, since the flux of the etching gases are greater than that of the deposition gases in doping steps of FIGS. 7A and 7B, thicknesses of doped layers may be reduced during doping. Thus, as described with reference to FIG. 3, a density profile of a doped layer may be increased. Also, the flux of an etching gas can be varied to adjust the amount or degree of etching of the doped layer.

FIGS. 8A and 8B illustrate plasma doping methods according to other embodiments of the present invention. Meanings of arrows and doping steps are similar to those described with reference to FIGS. 4A through 5B. FIG. 8A is a graph illustrating a doping step in which a deposition gas has a greater flux than an etching gas, and FIG. 8B is a graph illustrating a doping step in which an etching gas has a greater flux than a deposition gas.

Referring to FIG. 8A, a first source gas, a third source gas, and/or a mixture of the first and third source gases is supplied into a chamber at a substantially constant flux up to a time tᵢ₀ and a second source gas is supplied into the chamber at a substantially constant flux up to a time tᵢ in a doping step between tₛ and tᵢ. The first gas includes a component of a doped layer and deposits a new layer on the doped layer in the doping step. Also, the second gas etches the doped layer, and the third gas deposits a new layer on the doped layer to achieve a desired doping concentration. For example, the first, second, and third gases may be SiH₄, BF₃, and B₂H₆, respectively. Here, BF₃ may etch the polysilicon layer in a boron doping process, and SiH₄ and B₂H₆ may deposit a new polysilicon on the etched doped layer.

In FIG. 8B, a substantially constant flux of a first source gas, a third source gas, and/or a mixture of the first and third source gases are supplied up to a time tᵢ into a chamber, while a substantially constant flux of a second source gas is supplied up to a time tᵢ₀ into the chamber between tₛ and tᵢ. Accordingly, as described above with reference to FIGS. 8A and 8B, a deposition or etching gas can be selectively supplied for a portion of a doping process, to adjust a concentration or doping density of a doped layer. In addition, in some embodiments, the deposition and/or etching gases may be alternately supplied to achieve a desired doping.

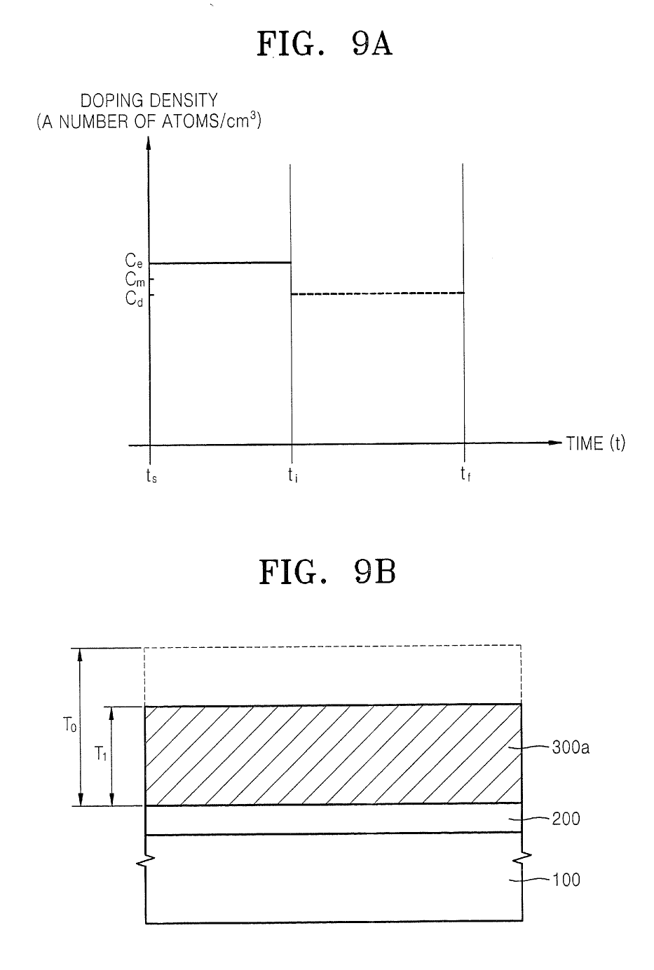

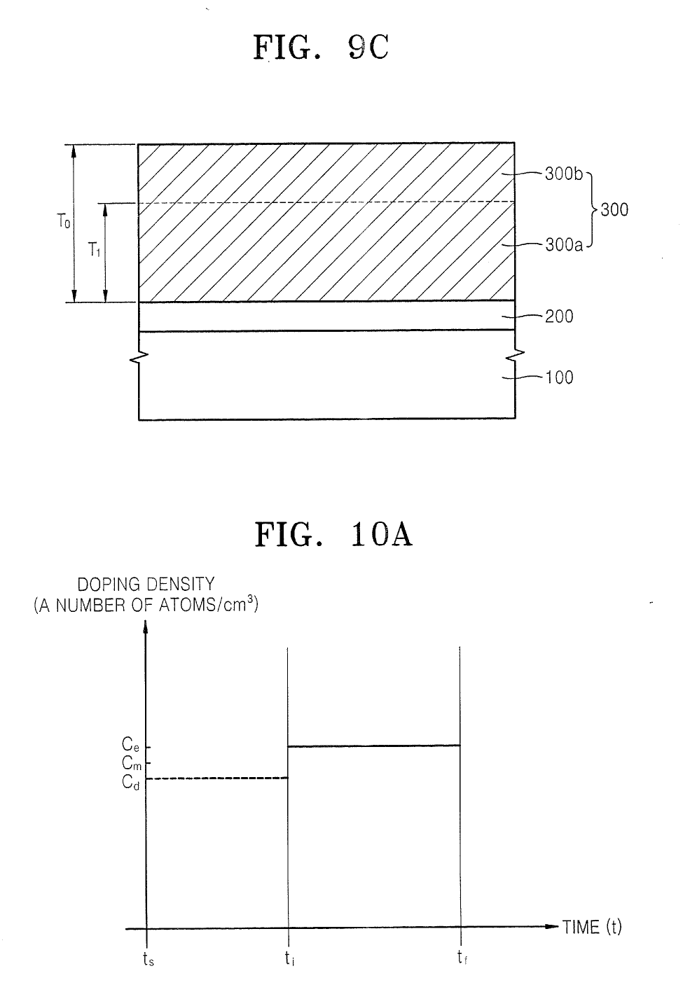

FIG. 9A is a graph illustrating plasma doping methods according to some embodiments of the present invention. FIG. 9B is a cross-sectional view illustrating a doping density of a doped layer in a doping step between tₛ and tᵢ, and FIG. 9C is a cross-sectional view illustrating a doping density of a doping layer in a doping step between tᵢ and t_{f}. As used herein, t_{f} denotes an ending time of a doping step or process. Reference character Cₘ denotes a doping density which is obtained by continuously offsetting a doping density achieved using an etching gas by a doping density achieved using a deposition gas during a doping process.

Referring to FIGS. 9A and 9B, an etching gas is provided at a greater flux than a deposition gas in a doping step between tₛ and tᵢ. A doped layer 300a, e.g., a polysilicon layer, is etched to cause a variation of a thickness thereof. In other words, a thickness of the doped layer is T₀ before doping but is reduced to T₁ after doping. After doping, a doping density Cₑ of the doped layer 300a is increased (i.e., is higher than the doping density Cₘ) due to a reduction of a thickness of the doped layer 300a. Here, the doping density Cₑ may be a doping density obtained after a thermal treatment is performed.

According to the above-described plasma doping method, doping is performed with a reduction of a doped layer. Thus, B may be doped adjacent the gate dielectric layer 200 of FIG. 2 at a relatively high density. As a result, an on-current of a PMOS can be improved, and a doping density can be increased with an application of a bias voltage.

Referring to FIGS. 9A and 9C, a deposition gas is provided at a greater flux than an etching gas in a doping step between tᵢ and t_{f}. A new polysilicon layer 300b is deposited on the doped layer 300a, e.g., a polysilicon layer, to cause a variation of a thickness of the doped layer 300. In other words, the thickness of the doped layer 300 is T₁ after the doping step between tₛ and tᵢ is completed, but is increased to T₀ in the doping step between tᵢ and t_{f}. A doping density C_{d} of the doped layer 300b is reduced (i.e., is lower than the doping density Cₘ) after the doping step between tᵢ and t_{f} is completed, due to an increase of a thickness of the doped layer 300. The doping density C_{d} may be a doping density obtained after a thermal treatment is performed.

In the above-described method, a doping density of an upper part of a doped layer can also be increased to reduce an electrical resistance when a metal electrode is formed on the doped layer. For example, a time required for performing the doping step between tᵢ and t_{f} can be increased to thereby increase a thickness of the doped layer 300 to a greater thickness T₂, and the doping step can be performed using an etching gas to increase the doping density of the upper part of the doped layer.

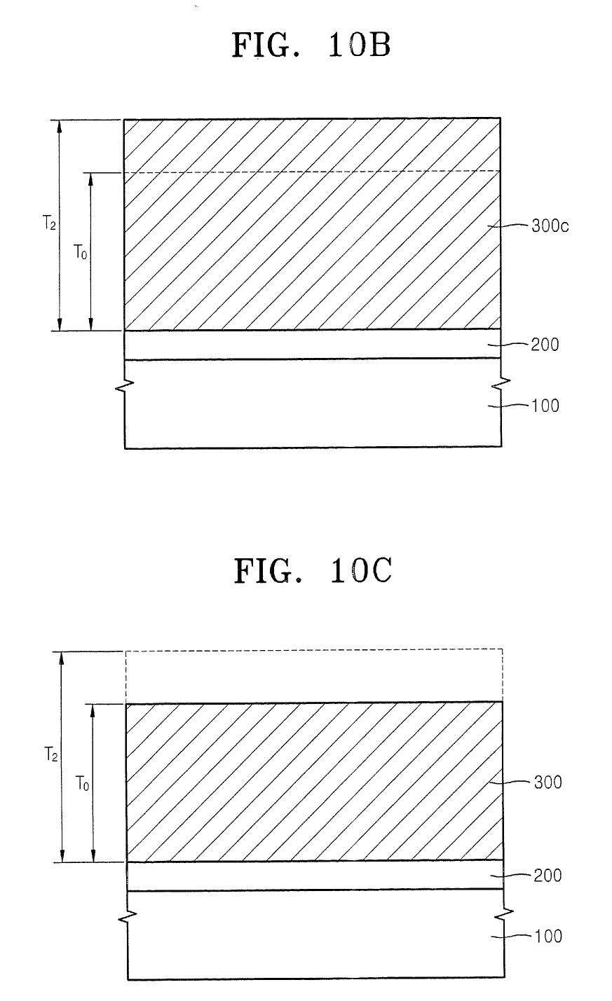

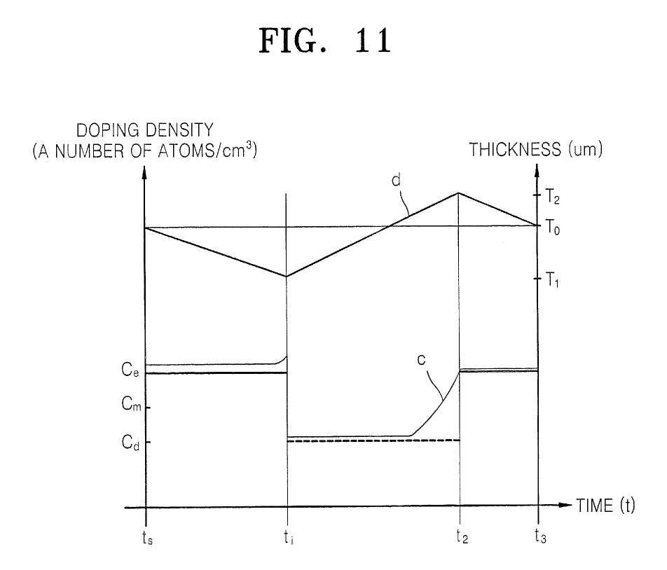

FIG. 10A is a graph illustrating plasma doping methods according to other embodiments of the present invention. FIG. 10B is a cross-sectional view illustrating a doping density of a doped layer in a doping step between tₛ and tᵢ, and FIG. 10C is a cross-sectional view illustrating a doping density of a doped layer in a doping step between tᵢ and t_{f}. Here, t_{f} denotes an ending time of the doping step.

Referring to FIGS. 10A and 10B, a deposition gas is provided at a greater flux than an etching gas in the doping step between tₛ and tᵢ. A new polysilicon layer is deposited on a doped layer, e.g., a polysilicon layer, to cause a variation of a thickness of the doped layer. In other words, the thickness of the doped layer is T₀ before the doping step is performed, but is increased to T₂ after the doping step is completed. A doping density C_{d} of a doped layer 300c is reduced (i.e., is lower than a doping density Cₘ) after the doping step between tₛ and tᵢ is completed, due to an increase of a thickness of the doped layer 300c. Here, the doping density C_{d} may be a doping density after a thermal treatment is performed.

Referring to FIGS. 10A and 10C, an etching gas is provided at a greater flux than a deposition gas in the doping step between tᵢ and t_{f}. A doped layer, e.g., a polysilicon layer, is etched to cause a variation of a thickness of the doped layer. In other words, a thickness of a doped layer 300 is T₂ after the doping step between tₛ and tᵢ is completed, but is reduced to T₀ after the doping step between tᵢ and t_{f} is completed. A doping density Cₑ of a doped layer 300 is increased (i.e., is higher than the doping density Cₘ) after doping, due to a reduction of a thickness of the doped layer 300. Accordingly, a doping density of an upper part of a doped layer having a thickness T₀ may be increased. Here, the doping density Cₑ may be a doping density obtained after a thermal treatment is performed.

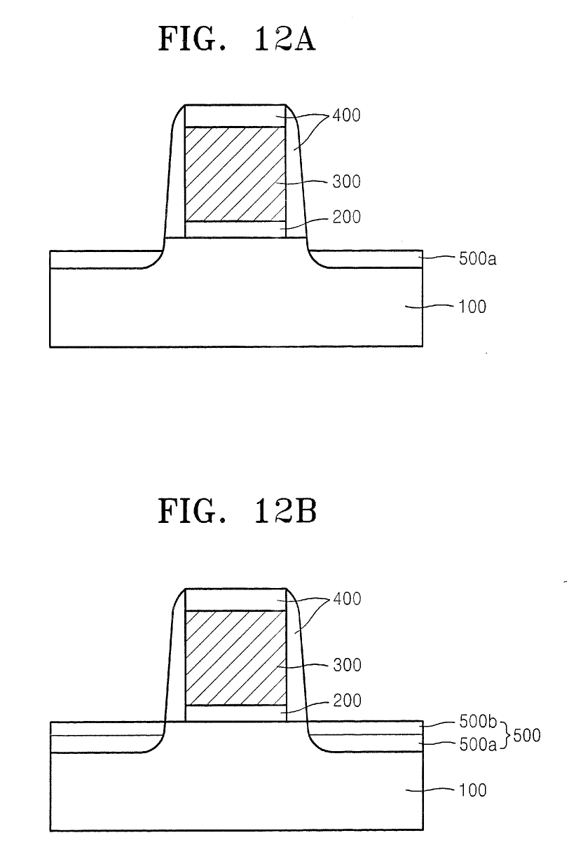

FIG. 11 is a graph illustrating variations in a doping density c and a thickness d in plasma doping methods according to some embodiments of the present invention. Here, a doping step may be sub-divided compared to the doping steps described with reference to FIGS. 9A through 10C. Thus, the plasma doping method may be referred to as a multi-step doping method.

Referring to FIG. 11, an etching gas is provided at a greater flux than a deposition gas in a doping step between tₛ and tᵢ in which a doping density Cₑ is higher than a doping density Cₘ. Also, a thickness of a doped layer is gradually decreased from T₀ to T₁ during the doping step between tₛ and tᵢ. The deposition gas is provided at a greater flux than the etching gas in a doping step between tᵢ and t₂ in which a doping density C_{d} is lower than the doping density Cₘ. Also, the thickness of the doping density is gradually increased from T₁ to T₂ during the doping step between tᵢ and t₂. The etching gas is again provided at a greater flux than the deposition gas in a doping step between t₂ and t₃ in which a doping density Cₑ is higher than the doping density Cₘ. Also, the thickness of the doped layer is decreased from T₂ back to T₀ during the doping step between t₂ and t₃.

The overall doping density c is slightly higher than the doping densities C_{d} and Cₑ of the doping steps between tᵢ and t₂ and between t₂ and t₃. This is because the overall doping density c may be affected by subsequent doping steps. If the process described with reference to FIG. 11 is applied to the structure of FIG. 2, a doping density of a polysilicon layer adjacent to the gate dielectric layer 200 may be relatively high, a doping density of an intermediate part of the polysilicon layer may be relatively low, and a doping density of an upper part of the polysilicon layer may be relatively high. Such resultₛ may contrast with the doping density depending on the doping depth described with reference to FIG. 3. In other words, in FIG. 3, the doping density of the polysilicon layer 300 is reduced in portions of the polysilicon layer 300 adjacent to the gate dielectric layer 200. However, in some embodiments, a doping density of portions of the polysilicon layer 300 adjacent the gate dielectric layer 200 can be increased.

FIGS. 12A and 12B are cross-sectional views illustrating plasma doping methods according to further embodiments of the present invention. Elements and/or operations as discussed below with reference to FIGS. 12A and 12B may be added to and/or used in conjunction with elements of FIG. 2. In particular, a process of forming source and/or drain areas of a transistor will be described in conjunction with plasma doping methods discussed below.

Referring to FIG. 12A, a gate dielectric layer 200 and a gate electrode 300 are sequentially stacked on a substrate 100. An anti-doping or mask layer 400 is formed, for example, of nitride on an upper surface of the gate electrode 300 and sidewalls of the gate electrode 300 and the gate dielectric layer 200. Next, plasma doping is performed on an exposed portion of the substrate 100, for example, using an etching gas as a second gas, e.g., phosphorous (P). Here, a portion of the exposed portion of the substrate 100 includes a first area 500a in which a source and/or drain region may be formed.

The etching gas may be a compound including P, and may etch the exposed portions of the substrate 100 and advances doping. Thus, a portion of the substrate 100 is removed, and P is doped in a first area 500a for the source and/or drain. Since doping is performed in the first area 500a as described above, P may be doped in the first area 500a at a relatively high density.

Referring to FIG. 12B, plasma doping is performed on an exposed portion of the substrate 100 using a deposition gas. The deposition gas may be a gas including a component of the substrate 100 (such as a first gas) or a compound including P (such as a third gas). Thus, the deposition gas deposits a new layer on the substrate 100. As a result, the thickness of the substrate 100 may be restored to its original thickness, and P may be doped in a second area 500b of the source and/or drain region. Since doping is performed during deposition of the new layer as described above, P may be doped in the second area 500b at a relatively lower doping density than in the first area 500a. Accordingly, the source and/or drain regions 500 may be divided into a first area 500a having a relatively high doping density and a second area 500b having a relatively low doping density.

As described above, in methods of plasma doping according to some embodiments of the present invention, a combination of an etching gas for etching a doped layer and a deposition gas for forming a new layer on the doped layer may be provided. Thus, a pre-doping thickness of the doped layer can be substantially maintained after doping. Also, doping using the etching gas can be combined with doping using the deposition gas to appropriately adjust a doping density according to a desired depth (or position).

While the present invention has been particularly shown and described with reference to exemplary embodiments thereof, it will be understood by those of ordinary skill in the art that various changes in form and details may be made therein without departing from the spirit and scope of the present invention as defined by the following claims. For example, the present invention has been described herein with reference to a PMOS transistor, but can also be applied to an n-channel metal-oxide semiconductor (NMOS) transistor and/or other devices.

That which is claimed:

1. A plasma doping method, comprising:
providing a substrate including a layer to be doped inside a chamber; and
supplying first and second source gases to the layer to achieve a desired doping concentration, the first source gas comprising a component configured to increase a thickness of the layer, and the second source gas comprising a component configured to reduce the thickness of the layer.

2. The method of claim 1, wherein supplying the first and second source gases comprises:
supplying the first and second source gases such that the thickness of the layer prior to plasma doping is substantially similar to that after the plasma doping is completed.

3. The method of claim 1, wherein the first source gas comprises a deposition gas configured to increase the thickness of the layer by a deposition process, and wherein the second source gas comprises an etching gas configured to reduce the thickness of the layer by an etching process.

4. The method of claim 1, wherein the layer comprises polysilicon.

5. The method of claim 1, wherein the layer comprises a metal thin film.

6. The method of claim 4, wherein the first source gas comprises SiH₄.

7. The method of claim 4, wherein the second source gas comprises fluorine.

8. The method of claim 7, wherein the second source gas comprises BF₃.

9. The method of claim 1, further comprising:
supplying a third source gas comprising a component configured to increase the thickness of the layer to achieve the desired doping concentration.

10. The method of claim 9, wherein the third source gas comprises a deposition gas including hydrogen that is configured to increase a thickness of the layer to achieve the desired doping concentration.

11. The method of claim 10, wherein the third source gas comprises B₂H₆.

12. The method of claim 1, wherein supplying the first and second source gases comprises:
supplying the first source gas for at least a portion of a time during which plasma doping is performed; and
supplying the second source gas for a greater portion of the time than the first source gas.

13. The method of claim 1, wherein supplying the first and second source gases comprises:
supplying the first source gas for at least a portion of a time during which plasma doping is performed; and
supplying the second source gas for a lesser portion of the time than the first source gas.

14. The method of claim 1, further comprising:
supplying a third source gas for at least a portion of a time during which plasma doping is performed,
and wherein supplying the second source gas comprises supplying the second source gas for a greater portion of the time than the third source gas.

15. The method of claim 1, wherein supplying the first and second source gases comprises:
supplying a mixture of the first source gas and a third source gas for at least a portion of a time during which plasma doping is performed; and
supplying the second source gas for a greater portion of the time than the mixture.

16. The method of claim 1, further comprising:
supplying a third source gas for at least a portion of a time during which plasma doping is performed,
and wherein supplying the second source gas comprises supplying the second source gas for a lesser portion of the time than the third source gas.

17. The method of claim 1, wherein supplying the first and second source gases comprises:
supplying a mixture of the first source gas and a third source gas for at least a portion of a time during which plasma doping is performed; and
supplying the second source gas for a lesser portion of the time than the mixture.

18. The method of claim 1, wherein supplying the first and second source gases comprises:
varying a flux of the first and/or second source gases to achieve the desired doping concentration.

19. The method of claim 18, wherein varying a flux of the first and/or second source gases comprises:
maintaining a flux of the second source gas at a substantially constant level for at least a portion of a time during which plasma doping is performed; and
increasing a flux of the first source gas for at least a portion of the time during which plasma doping is performed.

20. The method of claim 18, wherein varying a flux of the first and/or second source gases comprises:
maintaining a flux of the second source gas at a substantially constant level for at least a portion of a time during which plasma doping is performed; and
decreasing a flux of the first source gas for at least a portion of the time during which plasma doping is performed.

21. The method of claim 18, further comprising:
supplying a third source gas for at least a portion of a time during which plasma doping is performed,
wherein varying a flux of the first and/or second source gases comprises maintaining a flux of the second source gas at a substantially constant level for at least a portion of the time and increasing a flux of the third gas for at least a portion of the time.

22. The method of claim 18, further comprising:
supplying a third source gas for at least a portion of a time during which plasma doping is performed,
wherein varying a flux of the first and/or second source gases comprises maintaining a flux of the second gas at a substantially constant level for at least a portion of the time and decreasing a flux of the third source gas for at least a portion of the time.

23. The method of claim 1, wherein supplying the first and second source gases comprises:
alternately supplying the first and second source gases to the layer to achieve the desired doping concentration.

24. The method of claim 23, wherein alternately supplying the first and second source gases comprises:
supplying the second source gas to decrease the thickness of the layer for at least a portion of a time during which plasma doping is performed and the first source gas is not supplied.

25. The method of claim 23, wherein alternately supplying the first and second source gases comprises:
supplying the first source gas to increase the thickness of the layer for at least a portion of a time during which plasma doping is performed and the second source gas is not supplied.
